(19) United States
(12) Patent Application Publication
(10) Pub. No.: US 2026/0160818 A1
(43) Pub. Date: Jun. 11, 2026

(54) METHOD AND APPARATUS FOR ESTIMATING STATE OF BATTERY

(71) Applicant: HANWHA SOLUTIONS CORPORATION, Seoul (KR)

(72) Inventors: Jeong LEE, Seoul (KR); Jun Mo KIM, Seoul (KR)

(73) Assignee: HANWHA SOLUTIONS CORPORATION, Seoul (KR)

(21) Appl. No.: 19/400,069

(22) Filed: Nov. 25, 2025

(30) Foreign Application Priority Data
Dec. 5, 2024 (KR) 10-2024-0179906

(51) Int. Cl. G01R 31/3842; G01R 31/389

(52) U.S. Cl. CPC G01R 31/3842; G01R 31/389

(57) ABSTRACT

Provided are a method and apparatus for estimating a state of a battery. The method includes obtaining state information of the battery in a (k−1)^{th} cycle, estimating a state of charge (SOC) value of the battery in a k^{th} cycle based on the obtained state information of the battery, calculating an internal resistance value of the battery in the k^{th} cycle based on inflow power or outflow power of the battery in case that charge or discharge of the battery in the k^{th} cycle is terminated, and updating the state information of the battery in the k^{th} cycle using the calculated internal resistance value, in which k includes a natural number of at least 2.

### CROSS-REFERENCE TO RELATED APPLICATION

This application is based on and claims priority under 35 U.S.C. § 119 to Korean Patent Application No. 10-2024-0179906, filed on, Dec. 5, 2024, in the Korean Intellectual Property Office, the present disclosure of which is incorporated by reference herein in its entirety.

### BACKGROUND

### 1. Field

The present disclosure relates to a method and apparatus for estimating a state of a battery.

### 2. Description of the Related Art

Energy storage devices may include various devices that store energy. For example, an energy storage device may include at least one battery. A plurality of batteries may be connected in series and/or parallel to form the energy storage device.

Meanwhile, as a battery ages, an internal resistance thereof may increase. The increase in internal resistance of the battery is problematic as it may cause overcharging and overdischarging of the battery.

To ensure the safety of the energy storage device including the battery, an efficient method for estimating the state of the battery is required.

The above-mentioned background technology is technical information that the inventor possessed for deriving the present disclosure or acquired in the process of deriving the present disclosure, and may not be necessarily said to be known art disclosed to the general public before filing the application of the present disclosure.

### SUMMARY

The present disclosure provides a method and apparatus for estimating a state of a battery. The present disclosure provides a method and apparatus for estimating a state of a battery without using additional circuits, etc.

The problem that the present disclosure aims to solve is not limited to the problems mentioned above, and other problems and advantages of the present disclosure that are not mentioned may be understood through the following description and may be understood more clearly by the examples of the present disclosure. In addition, it will be appreciated that the problems and advantages to be solved by the present disclosure may be realized by means and combinations thereof indicated in the claims.

According to a first aspect of the present disclosure, a method of estimating a state of a battery includes obtaining state information of the battery in a (k−1)^{th} cycle, estimating a state of charge (SOC) value of the battery in a k^{th} cycle based on the obtained state information of the battery, calculating an internal resistance value of the battery in the k^{th} cycle based on inflow power or outflow power of the battery in case that charge or discharge of the battery in the k^{th} cycle is terminated, and updating the state information of the battery in the k^{th} cycle using the calculated internal resistance value, in which k includes a natural number of at least 2.

According to a second aspect of the present disclosure, an apparatus for estimating a state of a battery includes a memory in which at least one program is stored and a processor configured to perform an operation by executing the at least one program, in which the processor is further configured to obtain state information of the battery in a (k−1)^{th} cycle, estimate a state of charge (SOC) value of the battery in a k^{th} cycle based on the obtained state information of the battery, calculate an internal resistance value of the battery in the k^{th} cycle based on inflow power or outflow power of the battery in case that charge or discharge of the battery in the k^{th} cycle is terminated, and update the state information of the battery in the k^{th} cycle using the calculated internal resistance value, in which k includes a natural number of at least 2.

According to a third aspect of the present disclosure, a computer-readable recording medium having recorded thereon a program for executing the method according to the first aspect of the present disclosure on a computer is provided.

Other aspects, features, advantages, and advantages other than those described above will become apparent from the following figures, claims, and the detailed description of the present disclosure.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 schematically illustrates an apparatus for estimating a state of a battery and a battery according to an embodiment;

FIG. 2 is a block diagram of an apparatus for estimating a state of a battery according to an embodiment;

FIG. 3 is a flowchart illustrating a method of estimating a state of a battery by an apparatus for estimating a state of a battery, according to an embodiment;

FIG. 4 is a diagram for describing a method of obtaining state information of a battery by an apparatus for estimating a state of a battery according to an embodiment;

FIG. 5 is a diagram for describing a method of estimating a state of charge (SOC) value of a battery by an apparatus for estimating a state of a battery according to an embodiment;

FIG. 6 is a diagram for describing a method of calculating an internal resistance value of a battery by an apparatus for estimating a state of a battery according to an embodiment; and

FIG. 7 is a diagram illustrating a photovoltaic power generation system using an apparatus for estimating a state of a battery according to an embodiment.

### DETAILED DESCRIPTION

Advantages and features of the present disclosure, and a method of achieving them will be apparent with reference to the embodiments described in detail in conjunction with the drawings. However, the present disclosure is not limited to the embodiments presented below, but may be implemented in various different forms, and should be understood to include all transformations, equivalents, and substitutes included in the spirit and technical scope of the present disclosure. Embodiments presented below are provided to complete the present disclosure of the present disclosure and perfectly inform those of ordinary skill in the art of the category of the present disclosure. In describing the present disclosure, in case that it is determined that a detailed description of related known technologies may obscure the gist of the present disclosure, the detailed description thereof will be omitted.

The term used herein is used to describe particular embodiments, and is not intended to limit the present disclosure. Singular forms may include plural forms unless apparently indicated otherwise contextually. It should be understood that the term “include”, “have”, or the like used herein is to indicate the presence of features, numbers, steps, operations, elements, parts, or a combination thereof described in the specifications, and does not preclude the presence or addition of one or more other features, numbers, steps, operations, elements, parts, or a combination thereof.

Some embodiments of the present disclosure may be represented by functional block configurations and various processing steps. Some or all of the functional blocks may be implemented with various numbers of hardware and/or software configurations executing particular functions. In some embodiments, the functional blocks of the present disclosure may be implemented by one or more microprocessors or circuit configurations for certain functions. In some embodiments, functional blocks of the present disclosure may be implemented in various programming or scripting languages. Functional blocks may be implemented as algorithms running on one or more processors. The present disclosure may employ related art for electronic environment setting, signal processing, and/or data processing, etc. The term such as “mechanism”, “element”, “means”, or “configuration” may be used broadly and may not be limited to mechanical and physical configurations.

Additionally, connection lines or connection members between components shown in the drawings merely exemplify functional connections and/or physical or circuit connections. In an actual device, connections between components may be represented by various replaceable or additional functional connections, physical connections, or circuit connections.

Hereinafter, the present disclosure will be described in detail with reference to the attached drawings.

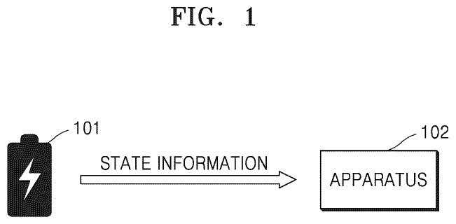

FIG. 1 schematically illustrates an apparatus for estimating a state of a battery and a battery according to an embodiment.

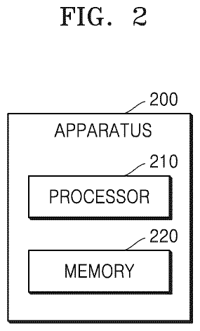

Hereinafter, an apparatus capable of implementing a method described below with reference to FIGS. 2 to 6 will be referred to as an apparatus 102 for estimating a state of a battery.

For example, at least one battery 101 may be combined to form an energy storage device. Herein, the energy storage device may convert power. For example, the energy storage device may convert alternating current (AC) power to direct current (DC) power, or DC power to AC power.

For example, the energy storage device may be, but is not limited to, an energy storage system included in a photovoltaic power generation system. For example, the energy storage device may be included in an electric vehicle, and any system using batteries may include energy storage devices.

In a process in which the energy storage device performs power conversion, losses due to power conversion such as charging loss, discharging loss, storage loss, etc., may occur. The charging loss may include energy loss occurring in a charging process of the battery 101. The discharging loss may include energy loss occurring in a discharging process of the battery 101. The storage loss may include energy loss occurring in a non-use period of the battery 101.

As the battery 101 ages, the internal resistance of the battery 101 may increase. The internal resistance may include resistance generated due to current flowing in the battery 101. A current capacity may decrease due to aging of the battery 101. The current capacity may refer to the amount of current that the battery 101 may supply for a certain period of time.

The internal resistance of the battery 101 may be used as an indicator to identify the state of the battery 101. For example, as the internal resistance of the battery 101 increases, loss due to power conversion occurring in the process in which the energy storage device performs power conversion may increase. As the internal resistance of the battery 101 increases, overcharging or overdischarging of the battery 101 may occur, reducing the safety of the energy storage device.

Therefore, a method of estimating the state of the battery 101 is required to increase the safety of the energy storage device. Conventional battery state estimation methods require a large amount of computation because of using complex calculation formulas. Accordingly, a method of estimating the state of the battery 101 without an additional circuit or a complex computational process is required.

The apparatus 102 for estimating a state of the battery 101 according to an embodiment may estimate the internal resistance of the battery 101 without an additional circuit, additional parameter measurement, resistor separation, or a complex computational process, using a method described below with reference to FIGS. 2 to 6. The apparatus 102 for estimating the state of the battery 101 may estimate the state of the battery 101 based on a state of charge (SOC) and internal resistance of the battery 101. Thus, the safety of the energy storage device including the battery 101 may be secured.

A detailed method of estimating the state of the battery 101 by the apparatus 102 for estimating the state of the battery 101 according to the present disclosure will be described later with reference to FIGS. 2 to 6.

FIG. 2 is a block diagram of an apparatus for estimating a state of a battery according to an embodiment.

Referring to FIG. 2, an apparatus 200 for estimating the state of the battery may include a processor 210 and a memory 220.

The apparatus 200 for estimating the state of the battery of FIG. 2 may be identical to the apparatus 102 for estimating the state of battery of FIG. 1.

The memory 220 may be hardware that stores various data processed in the apparatus 200 for estimating the state of the battery and may store programs for processing and control of the processor 210.

The memory 220 may include random access memory (RAM) such as dynamic random access memory (DRAM), static random access memory (SRAM), etc., read-only memory (ROM), electrically erasable programmable read-only memory (EEPROM), CD-ROM, Blu-ray or other optical disk storages, hard disk drive (HDD), solid state drive (SSD), or flash memory.

The processor 210 may control an overall operation of the apparatus 200 for estimating the state of the battery. For example, the processor 210 may control overall the memory 220, etc., by executing programs stored in the memory 220.

The processor 210 may control the operation of the apparatus 200 for estimating the state of the battery by executing the programs stored in the memory 220. The processor 210 may control at least some of operations of the apparatus 200 for estimating the state of the battery.

For example, the processor 210 may obtain state information of the battery in a (k−1)^{th} cycle, estimate the SOC value of the battery in a k^{th} cycle based on the obtained state information of the battery, calculate the internal resistance value of the battery in the k^{th} cycle based on the inflow or outflow power of the battery when charge or discharge of the battery in the k^{th} cycle is completed, and update the state information of the battery in the k^{th} cycle using the calculated internal resistance value. k may include a natural number of at least 2.

In another example, the processor 210 may obtain state information including at least one of the internal resistance value, charge/discharge current, and an open circuit voltage of the battery.

In another example, the processor 210 may obtain the state information of the battery by obtaining the internal resistance value of the battery calculated in an immediately preceding cycle.

In another example, the processor 210 may obtain the state information of the battery in the (k−1)^{th} cycle corresponding to an internal resistance value included in a data sheet of the battery for k of 2.

In another example, the processor 210 may estimate the SOC value of the battery based on a charge/discharge state of the battery.

In another example, the processor 210 may calculate an initial value of the SOC using the open circuit voltage of the battery and the internal resistance value of the battery, and estimate the SOC value based on the initial value of the SOC after completion of charge or discharge of the battery.

In another example, the processor 210 may estimate the SOC value by combining the initial value of the SOC after completion of charge or discharge of the battery with an accumulated value of an inflow current corresponding to charging.

In another example, the processor 210 may calculate the inflow or outflow power of the battery based on the power loss caused by the internal resistance of the battery.

In another example, the processor 210 may estimate the SOC value of the battery in a (k+1)^{th} cycle based on the updated state information.

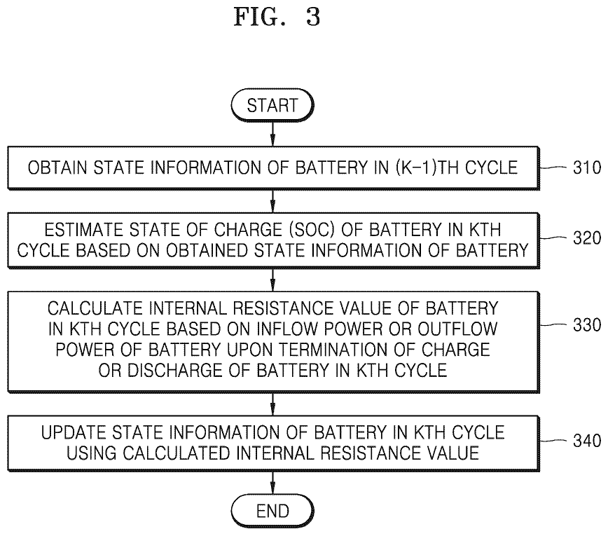

A detailed description of various operations of the apparatus 200 for estimating the state of the battery that may be performed by the processor 210 will be described later with reference to FIGS. 3 to 6.

The processor 210 may be implemented using at least one of application specific integrated circuits (ASICs), digital signal processors (DSPs), digital signal processing devices (DSPDs), programmable logic devices (PLDs), field programmable gate arrays (FPGAs), controllers, microcontrollers, microprocessors, and other electrical units for performing functions.

In an embodiment, a process performed in the apparatus 200 for estimating the state of the battery may be performed by an electronic device having mobility.

FIG. 3 is a flowchart illustrating a method of estimating a state of a battery by an apparatus for estimating a state of a battery, according to an embodiment.

In operation 310, the processor 210 may obtain state information of the battery in the (k−1)^{th} cycle.

In an embodiment, the state information of the battery may include at least one of the internal resistance value, the charge/discharge current, and the open circuit voltage of the battery.

The internal resistance of the battery may include resistance generated due to current flowing in the battery. The internal resistance of the battery may affect performance, power transfer efficiency, and heat generation of the battery. The internal resistance value of the battery may include a value that numerically represents the internal resistance of the battery.

The charge/discharge current may include charge current and discharge current. charge current may include current supplied to a battery to increase energy stored within the battery, and discharge current may include current flowing when the battery supplies energy to a power consuming device.

An open circuit voltage (OCV) may include the voltage of the battery measured when no current flows through the battery. A state in which no current flows through the battery may include a state in which no load is connected to terminals of the battery.

In an embodiment, the processor 210 may obtain the internal resistance value of the battery calculated in the immediately preceding cycle.

A cycle may include at least one of a process of the battery reaching a fully discharged state from a fully charged state and a process of the battery reaching the fully charged state from the fully discharged state.

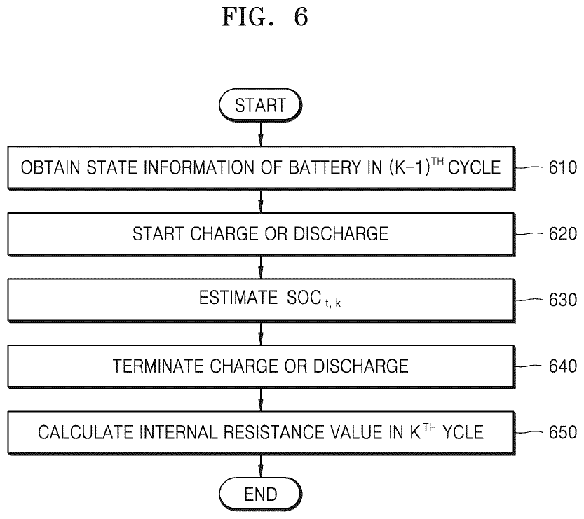

A detailed description of a method, performed by the processor 210, of calculating the internal resistance value of the battery will be described later with reference to FIG. 6.

In an example, the processor 210 may obtain the state information of the battery in the (k−1)^{th} cycle corresponding to the internal resistance value included in the data sheet of the battery for k of 2.

For example, the processor 210 may obtain the internal resistance value of the battery included in the data sheet of the battery if there is no previously calculated internal resistance value. The data sheet may refer to materials in which information such as performance information of the battery is recorded. The performance information of the battery may include the internal resistance value of the battery.

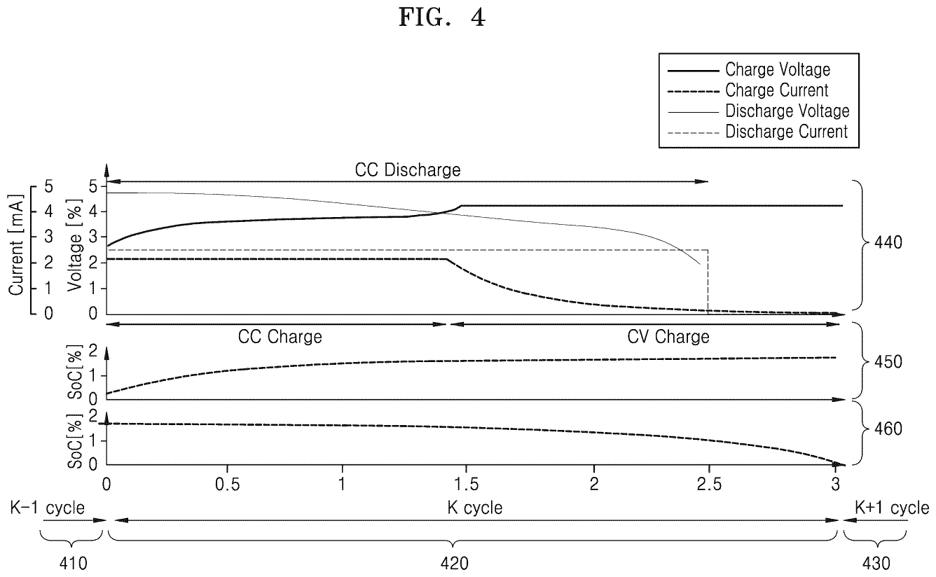

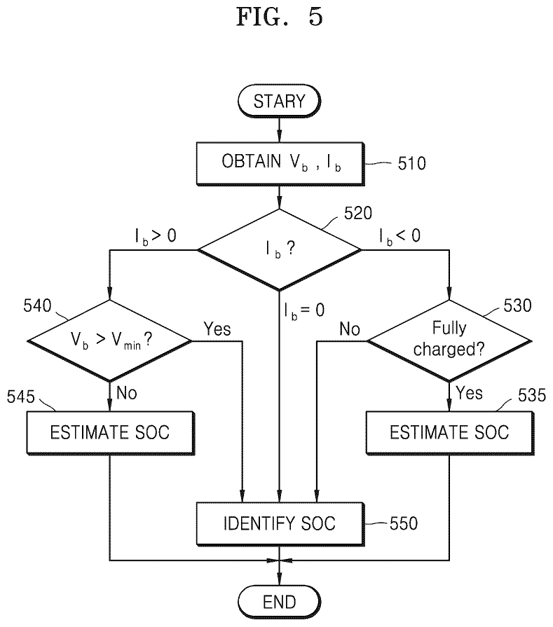

Hereinbelow, a specific example of operation 310 will be described with reference to FIGS. 4 and 5.

In operation 320, the processor 210 according to the present disclosure may estimate the SOC value of the battery in the k^{th} cycle based on the acquired state information of the battery.

In an embodiment, the processor 210 may estimate the SOC value of the battery based on a charge/discharge state of the battery.

In an embodiment, the processor 210 may calculate an initial value of the SOC using the open circuit voltage of the battery and the internal resistance value of the battery, and estimate the SOC value based on the initial value of the SOC after completion of charge or discharge of the battery.

In an embodiment, the processor 210 may estimate the SOC value by combining the initial value of the SOC after completion of charge or discharge of the battery with an accumulated value of an inflow current corresponding to charging.

Hereinbelow, a specific example of operation 320 will be described with reference to FIG. 5.

In operation 330, the processor 210 according to the present disclosure may calculate the internal resistance value of the battery in the k^{th} cycle based on the inflow or outflow power of the battery when the charge or discharge of the battery in the k^{th} cycle is terminated.

In an embodiment, the inflow power or outflow power of the battery may be calculated based on power loss caused by the internal resistance of the battery.

Hereinbelow, a specific example of operation 330 will be described with reference to FIG. 6.

In operation 340, the processor 210 according to the present disclosure may update the state information of the battery in the k^{th} cycle using the calculated internal resistance value.

In an embodiment, the processor 210 may estimate the SOC value of the battery in the (k+1)^{th} cycle based on the updated state information.

Hereinbelow, a specific example of operation 340 will be described with reference to FIG. 6.

FIG. 4 is a diagram for describing a method of obtaining state information of a battery by an apparatus for estimating a state of a battery according to an embodiment.

In an embodiment, the processor 210 may obtain the state information of the battery. For example, the processor 210 may obtain the state information of the battery in the (k−1)^{th} cycle. The state information of the battery according to an embodiment may include at least one of the internal resistance value, the charge/discharge current, and the open circuit voltage of the battery.

As described above, the internal resistance of the battery may include resistance generated due to current flowing in the battery. The internal resistance of the battery may affect performance, power transfer efficiency, and heat generation of the battery. The internal resistance value of the battery may include a value that numerically represents the internal resistance of the battery.

The charge/discharge current may include charge current and discharge current. The charge current may include current supplied to a battery to increase energy stored within the battery, and the discharge current may include current flowing when the battery supplies energy to a power consuming device.

The open circuit voltage may include the voltage of a battery measured in a state where no current flows through the battery. The state in which no current flows through the battery may include a state in which no load is connected to terminals of the battery.

In an embodiment, the processor 210 may obtain the internal resistance value of the battery calculated in the immediately preceding cycle. The immediately preceding cycle may mean the (k−1)^{th} cycle.

Cycles 410, 420, and 430 may include at least one of a process in which the battery reaches the fully discharged state from the fully charged state and a process in which the battery reaches the fully charged state from the fully discharged state.

Referring to FIG. 4, a graph 460 showing the SOC value of the battery in the process of reaching the fully discharged state from the fully charged state and a graph 450 showing the SOC value of the battery in the process of reaching the fully charged state from the fully discharged state are illustrated.

The SOC is an indicator of the amount of charge stored in the battery, and may include a value expressed as a percentage of the amount of charge currently stored in the battery compared to a rated capacity of the battery. The SOC value may include the aforementioned percentage value.

As described above, the processor 210 according to an embodiment may obtain the internal resistance value of the battery calculated in the immediately preceding cycle.

For example, the processor 210 may obtain the internal resistance value of the battery calculated in the (k−1)^{th} cycle 410. The processor 210 may estimate the SOC value of the battery in the k^{th} cycle 420 by using the obtained internal resistance value of the battery calculated in the (k−1)^{th} cycle 410.

k is a natural number of at least 2 and may be a variable used to express the order of a cycle. The (k−1)^{th} cycle 410 may be expressed as ‘K−1 cycle’. For example, when the processor 210 performs a battery state estimation method according to the present disclosure in the k^{th} cycle 420, the immediately preceding cycle may mean the (k−1)^{th} cycle 410, and the immediately following cycle may mean the (k+1)^{th} cycle 430.

A detailed method, performed by the processor 210, of estimating the SOC value of the battery according to an embodiment will be described later with reference to FIG. 5.

Referring to FIG. 4, a graph 440 showing charge voltage, charge current, discharge voltage, and discharge current in the kth cycle 420 is illustrated.

The charging process of the battery may include constant current charge (CC charge) and constant voltage charge (CV charge). The constant current charge may mean a method of supplying constant current for charge, and the constant voltage charge may mean a method of gradually reducing the charge current to maintain a constant voltage of the battery for charge.

The discharging process of the battery may include constant current discharge (CC discharge). The constant current discharge may mean a method of releasing energy while maintaining a constant current during the discharging process of the battery.

FIG. 5 is a diagram for describing a method of estimating an SOC value of a battery by an apparatus for estimating a state of a battery according to an embodiment.

In an embodiment, the processor 210 may estimate the SOC value of the battery based on state information of the battery. For example, the processor 210 may estimate the SOC value of the battery by using the state information of the battery including the internal resistance value, charge/discharge current, and open circuit voltage of the battery.

In an embodiment, the processor 210 may estimate the SOC value of the battery based on a charge/discharge state of the battery.

In operation 510, the processor 210 may obtain the voltage of the battery and the charge/discharge current value of the battery. For example, the processor 210 may measure the voltage of the battery using a voltage sensor or the like. The processor 210 may measure the charge/discharge current value of the battery using a current sensor or the like.

A way for the processor 210 to obtain the voltage and the charge/discharge current of the battery and available sensors are not limited to those described above.

In operation 520, the processor 210 may determine whether the charge/discharge current value is positive, negative, or 0.

For example, the processor 210 may perform operation 540 in case that the charge/discharge current value is positive. For example, in case that the charge/discharge current value is positive, the processor 210 may determine that the battery is being discharged, and perform operation 540.

In another example, the processor 210 may perform operation 530 in case that the charge/discharge current value is negative. For example, in case that the charge/discharge current value is negative, the processor 210 may determine that the battery is being charged, and perform operation 530.

In another example, the processor 210 may perform operation 550 in case that the charge/discharge current value is 0.

As such, the processor 210 may estimate the SOC value of the battery based on a charge/discharge state of the battery.

In operation 550, the processor 210 may identify the SOC value.

For example, the processor 210 may identify the SOC value of the battery using a battery management system (BMS). The BMS may calculate the SOC value of the battery by using various sensors, including a voltage sensor, a current sensor, etc., and various algorithms.

For example, the processor 210 may identify the SOC value of the battery using the SOC value of the battery calculated by the BMS.

As described above, the processor 210 may perform operation 540 in case that the charge/discharge current value is positive.

In operation 540, the processor 210 may compare the voltage of the battery with a minimum voltage of the battery. The minimum voltage of the battery may include a minimum voltage set for battery protection.

The processor 210 may discharge the battery until the voltage of the battery becomes equal to the minimum voltage of the battery in case that the voltage of the battery is greater than the minimum voltage of the battery. Through the above-described process, in case that the voltage of the battery becomes equal to or less than the minimum voltage of the battery, the processor 210 may perform operation 545.

The processor 210 may identify the SOC value by performing operation 550 in case that the voltage of the battery is greater than the minimum voltage of the battery. A detailed description of operations that the processor 210 may perform in operation 550 is omitted as they are described above with reference to operation 550.

As described above, the processor 210 may perform operation 530 in case that the charge/discharge current value is negative.

In operation 530, the processor 210 may determine whether the battery is fully charged.

For example, in case that the processor 210 determines that the battery is not fully charged, the processor 210 may fully charge the battery. Through the above-described process, in case that the battery is fully charged, the processor 210 may perform operation 535.

In case that the processor 210 determines that the battery is not fully charged, the processor 210 may perform operation 550 to identify the SOC value. A detailed description of operation 550 is omitted as operation 550 has been described above.

Hereinbelow, a method, performed by the processor 210, of estimating the SOC value of the battery in operations 535 and 545 will be described.

In an embodiment, the processor 210 may calculate the initial value of the SOC by using the open circuit voltage of the battery and the internal resistance value of the battery.

For example, the processor 210 may calculate the initial value of the SOC by using the open circuit voltage of the battery and the internal resistance value of the battery using an equation based on a voltage drop.

The equation based on the voltage drop that may be used by the processor 210 may include the following Equation 1.

$${SoC}_{0 , k} = {V}_{ocv} \pm ( {I}_{b} \times {R}_{b , k - 1} ) \qquad [ Equation 1 ]$$

In Equation 1, SoC_{0,k} may mean the initial value of the SOC in the k^{th} cycle, and R_{b,k-1} may mean the internal resistance value of the battery in the (k−1)^{th} cycle. V_{ocv} and I_{b} may mean each open circuit voltage and charge/discharge current.

The processor 210 according to an embodiment may calculate the initial value of the SOC by using the open circuit voltage of the battery and the internal resistance value of the battery, calculated in the immediately preceding cycle. For example, the processor 210 may obtain the internal resistance value of the battery calculated in the immediately preceding cycle and substitute the obtained internal resistance value into Equation 1 described above to calculate the initial value of the SOC.

In this way, the processor 210 may estimate the state of the battery by using the internal resistance value of the battery calculated in the immediately preceding cycle, thereby providing a more accurate battery state estimation method that reflects the state of the battery in the immediately preceding cycle.

In an embodiment, for k of 2, the state information of the battery in the (k−1)^{th} cycle may correspond to the internal resistance value included in the data sheet of the battery.

For example, the processor 210 may obtain the internal resistance value of the battery included in the data sheet of the battery if there is no previously calculated internal resistance value. For example, the processor 210 may obtain the internal resistance value of the battery by receiving the internal resistance value of the battery recorded in the data sheet.

In an embodiment, the processor 210 may estimate the SOC value based on the initial value of the SOC after completion of charge or discharge of the battery.

For example, the processor 210 may determine whether charge or discharge of the battery is completed in operations 530 and 540 described above, and estimate the SOC value based on the initial value of the SOC in case that charge or discharge of the battery is completed. The initial value of the SOC may be a value calculated through the process described above.

The detailed method, performed by the processor 210, of calculating the initial value of the SOC has been described above, and thus will be omitted.

In an embodiment, the processor 210 may estimate the SOC value by combining the initial value of the SOC after completion of charge or discharge of the battery with an accumulated value of inflow current corresponding to charge.

In another embodiment, the processor 210 may estimate the SOC value by combining the initial value of the SOC after completion of charge or discharge of the battery with an accumulated value of outflow current corresponding to discharge.

For example, the processor 210 may estimate the SOC value using Equation 2 and/or Equation 3 below.

$${SoC}_{t , k} = {SoC}_{0 , k} + \frac{1}{{C}_{t , k}} {\int }_{0}^{t} idt \qquad [ Equation 2 ]$$

$${SoC}_{t , k} = {SoC}_{0 , k} - \frac{1}{{C}_{t , k}} {\int }_{0}^{t} idt \qquad [ Equation 3 ]$$

In Equation 2 and Equation 3, C_{t,k} may mean the rated capacity of the battery over time in the k^{th} cycle. SoC_{t,k} may mean the SOC value over time in the k^{th} cycle, and SoC_{0,k} may be the initial value of the SOC in the k^{th} cycle, and may include a value calculated by the processor 210 through the above-described process.

For example, the processor 210 may estimate the SOC value of the battery that changes over time during charge by using Equation 2 described above. In another example, the processor 210 may estimate the SOC value of the battery that changes over time during discharge by using Equation 3 described above.

In this way, the processor 210 may estimate the SOC value of the battery without using an additional circuit, a filter requiring complex calculations, etc., thereby providing a more efficient battery state estimation method with a reduced calculation amount.

The processor 210 may also estimate the SOC value using the initial value of the SOC calculated using the internal resistance of the battery calculated in the immediately preceding cycle, thereby providing a more accurate battery state estimation method that reflects the state of the battery in the immediately preceding cycle.

FIG. 6 is a diagram for describing a method of calculating an internal resistance value of a battery by an apparatus for estimating a state of a battery according to an embodiment.

In operation 610, the processor 210 may obtain state information of the battery in the (k−1)^{th} cycle. A detailed description of operation 610 is omitted as operation 610 has been described above with reference to FIG. 4.

In operation 620, the processor 210 may start charge or discharge. This may be for the processor 210 to estimate the SOC value of the battery that changes over time during charge or discharge.

For example, in case that the processor 210 determines in operation 540 of FIG. 5 that the voltage of the battery is equal to or less than the minimum voltage of the battery, the processor 210 may start charge. In another example, the processor 210 may start discharge in case that the processor 210 determines in operation 530 of FIG. 5 that charge of the battery is completed.

In operation 630, the processor 210 may estimate the SOC value over time. For example, the processor 210 may estimate the SOC value that changes over time in the k^{th} cycle.

The detailed method, performed by the processor 210, of estimating the SOC value is omitted as the detailed method has been described above with reference to operations 535 and 545 of FIG. 5.

In operation 640, the processor 210 may terminate charge or discharge of the battery. For example, the processor 210 may terminate charge in case that the battery is determined to be fully charged, and terminate discharge in case that the voltage of the battery becomes equal to or less than the minimum voltage of the battery.

In operation 650, the processor 210 may calculate the internal resistance value of the battery in the k^{th} cycle.

In an embodiment, the processor 210 may calculate the internal resistance value based on the inflow or outflow power of the battery in case that charge or discharge of the battery is terminated.

In an embodiment, the processor 210 may calculate the inflow power or the outflow power based on the power loss caused by the internal resistance of the battery. For example, the processor 210 may calculate the inflow power or the outflow power of the battery using Equation 4 below. The inflow power may include power supplied to the battery from outside, and the outflow power may include power discharged from the battery to outside.

$${I}_{b} \times {V}_{ocv} - {I}_{b}^{2} \times {R}_{b , k} - {η}_{b , k} \times {P}_{S} = 0 \qquad [ Equation 4 ]$$

In Equation 4, I_{b} may mean the charge/discharge current, V_{ocv} may mean the open circuit voltage, and n_{b,k} may mean a coefficient representing the efficiency of the battery in the k^{th} cycle. P_{S} may mean the power that the battery may supply, and R_{b,k} may mean the internal resistance of the battery in the k^{th} cycle.

A product of the charge/discharge current and the open circuit voltage may represent the power supplied to the battery and may be included in the inflow power. A product of a square of the charge/discharge current and the internal resistance of the battery in the k^{th} cycle may represent the power consumed due to the internal resistance of the battery and may be included in the outflow power. A product of the coefficient representing the efficiency of the battery and the power that the battery may supply may represent the power that the battery releases to outside, and may be included in the outflow power.

The power that the battery may supply, P_{S}, may be expressed as a product of the charge/discharge current I_{b} and the open circuit voltage V_{ocv}.

The processor 210 may calculate the internal resistance value of the battery using Equation 5 that may be derived using the above-described Equation 4.

$${R}_{b , k} = {V}_{ocv} \times ( \frac{1 - {η}_{b , k}}{{I}_{b}} ) \qquad [ Equation 5 ]$$

Equation 5 may be a result of expressing a suppliable power of Equation 4 as a product of the charge/discharge current and the open circuit voltage and then organizing the equation.

In this way, the processor 210 may measure the internal resistance of the battery without using an additional circuit, a filter requiring complex calculations, etc., thereby providing a more efficient battery state estimation method with a reduced calculation amount.

In an embodiment, the processor 210 may update the state information of the battery in the k^{th} cycle using the calculated internal resistance value.

For example, the processor 210 may update the state information of the battery in the k^{th} cycle by using the internal resistance value of the battery obtained through the process described above in the k^{th} cycle.

In an embodiment, the processor 210 may estimate the SOC value of the battery in the (k+1)^{th} cycle based on the updated state information.

For example, the processor 210 may estimate the SOC value of the battery in the (k+1)^{th} cycle based on the updated state information including the internal resistance value in the k^{th} cycle. A detailed description of a method, performed by the processor 210, of estimating the SOC value of the battery will be omitted as the method has been described above with reference to FIG. 5.

In this way, the processor 210 may calculate the internal resistance of the battery without an additional circuit and parameter measurement, thereby providing a more simplified battery state estimation method. The processor 210 may also estimate the SOC value of the battery in the (k+1)^{th} cycle by using the internal resistance value of the battery calculated in the k^{th} cycle, thereby providing a more accurate battery state estimation method that reflects the state of the battery in the immediately preceding cycle.

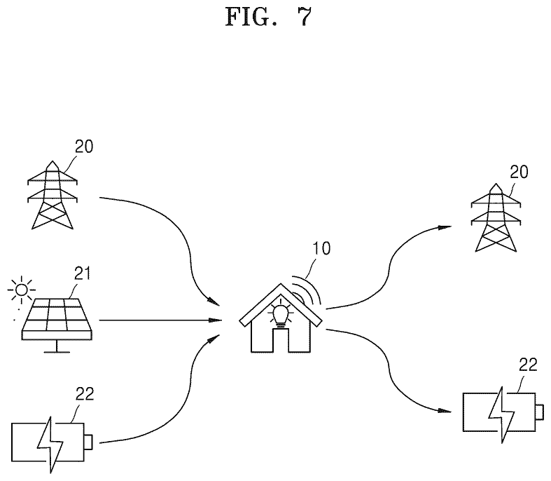

FIG. 7 is a diagram illustrating a photovoltaic power generation system using an apparatus for estimating a state of a battery according to an embodiment.

Referring to FIG. 7, electric power may be imported to a load 10 from at least one of a power grid 20, a photovoltaic module 21, and an energy storage system 22. Power may mean electric energy supplied to the load 10 for a unit time.

The load 10 may refer to an object that consumes power. For example, the load 10 may refer to a device that is installed in an electricity consumer user such as a house, a commercial facility, a factory, etc., and requires electric power. In some embodiments, in case that the electricity consumer receiving power is a house, the load 10 may include a refrigerator, a washing machine, an electric heating appliance, etc., installed in the house.

The power grid 20, which is an infrastructure system for generating, transmitting, and distributing power, may include power plants, substations, power grids, and so forth. The power generated in a power plant of the power grid 20 may be supplied to the load 10 and/or the energy storage system 22.

The photovoltaic module 21, which is a device that converts solar energy into electric energy, may include photovoltaic panels, photovoltaic cell cells, etc. In case that a plurality of photovoltaic modules 21 are connected, a photovoltaics module array may be formed.

For example, the photovoltaic module 21 may absorb solar energy through a photovoltaic panel, photoelectrically transform the absorbed solar energy into electric energy through a micro-inverter, and transmit the electric energy to an output terminal. The photovoltaic module 21 may continuously generate power while the sun is shining, with the daily power generation amount fluctuating depending on factors such as weather, such that a storage device such as the energy storage system 22 may be required.

The energy storage system 22 may store at least a part of the electric energy produced from the power grid 20 and/or photovoltaic module 21 for use when needed. The energy storage system 22 may be used to improve the stability of the power grid 20 and maintain consistency in electricity supply by storing electric energy during times when an electricity demand is low and using the same later during times when the electricity demand is high. The load 10 may be supplied with power by discharging the battery included in the energy storage system 22.

The remaining surplus power after responding to the power demand of the load 10 may be supplied (exported) to the power grid 20 or the energy storage system 22.

The apparatus for estimating the state of the battery, described above with reference to FIGS. 1 to 6, may estimate the state of the battery included in the energy storage system 22. For example, the apparatus for estimating the state of the battery according to an embodiment may be included in the energy storage system 22 and used to estimate the state of the battery included in the energy storage system 22.

As the detailed method, performed by the apparatus for estimating the state of the battery, of estimating the state of the battery according to the present disclosure has been described above with reference to FIGS. 2 to 6, a detailed description thereof will be omitted.

The apparatus for estimating the state of the battery according to an embodiment of the present disclosure may be used to estimate the state of the battery included in the energy storage system 22 in the photovoltaic power generation system, but its use is not necessarily limited to those described above.

An embodiment of the present disclosure described above may be implemented in the form of a computer program executable on a computer through various components, and the computer program may be recorded on a computer-readable medium.

The medium may include a hardware device specially configured to store and execute a program instruction, like a magnetic medium such as a hard disk, a floppy disk, and a magnetic tape, an optical recording medium such as a CD-ROM and a DVD, a magneto-optical medium such as a floptical disk, ROM, RAM, flash memory, etc.

Meanwhile, the computer program may be a program command specially designed and configured for the present disclosure or a program command known to be used by those of ordinary skill in the art of the computer software field. Examples of the computer program may include not only a machine language code created by a complier, but also a high-level language code executable by a computer using an interpreter.

According to the present disclosure described above, the state of the battery may be estimated efficiently using a method and apparatus for estimating the state of the battery without using an additional circuit, etc.

Certain executions described here are embodiments of the present disclosure, not limiting the scope of the present disclosure in any way. For the brevity of the specification, the description of conventional electronic configurations, control systems, software, and other functional aspects of the systems may be omitted. Connections of lines or connection members between components shown in the drawings are illustrative of functional connections and/or physical or circuit connections, and in practice, may be represented as alternative or additional various functional connections, physical connections, or circuit connections. In addition, when there is no specific mentioning, such as “essential” or “important”, it may not be a necessary component for the application of the present disclosure.

In the specification (especially, claims) of the present disclosure, the use of the term “the” and similar indicators thereof may correspond to both the singular and the plural. In addition, when the range is described in the present disclosure, the range includes the invention to which an individual value falling within the range is applied (unless stated otherwise), and is the same as the description of an individual value constituting the range in the detailed description of the present disclosure.

If there is no apparent description of the order of operations constituting the method according to the embodiments or a contrary description thereof, the operations may be performed in an appropriate order. However, the present disclosure is not necessarily limited according to the describing order of the operations. The use of all examples or exemplary terms (for example, etc.) in the present disclosure are to simply describe the present disclosure in detail, and unless the range of the present disclosure is not limited by the examples or the exemplary terms unless limited by the claims. It may be understood by those of ordinary skill in the art that various modifications, combinations, and changes may be made according to design conditions and factors within the scope of the appended claims or equivalents thereof.

Thus, the spirit of the present disclosure should not be determined by being limited to the above-described embodiments, and not only the claims to be described later, but also any range equivalent to or equivalently changed from the claims falls within the scope of the spirit of the present disclosure.

What is claimed is:

1. A method of estimating a state of a battery, the method comprising:
^{th} cycle;
estimating a state of charge (SOC) value of the battery in a k^{th} cycle based on the obtained state information of the battery;
calculating an internal resistance value of the battery in the k^{th} cycle based on inflow power or outflow power of the battery in case that charge or discharge of the battery in the k^{th} cycle is terminated; and
updating the state information of the battery in the k^{th} cycle using the calculated internal resistance value,
wherein k comprises a natural number of at least 2.

2. The method of claim 1, wherein the state information comprises at least one of the internal resistance value, charge/discharge current, and open circuit voltage of the battery.

3. The method of claim 1, wherein the cycle comprises at least one of a process of the battery reaching a fully discharged state from a fully charged state and a process of the battery reaching the fully charged state from the fully discharged state.

4. The method of claim 1, wherein in case that k is 2, the state information of the battery in the (k−1)^{th} cycle corresponds to the internal resistance value included in a data sheet of the battery.

5. The method of claim 1, wherein the estimating comprises estimating the SOC value of the battery based on the charge/discharge state of the battery.

6. The method of claim 5, wherein the estimating comprises:
calculating an initial value of the SOC using the open circuit voltage of the battery and the internal resistance value of the battery; and
estimating the SOC value based on the initial value of the SOC after completion of charge or discharge of the battery.

7. The method of claim 6, wherein the estimating comprises estimating the SOC value by combining an accumulated value of current flowing in according to the charge with the initial value of the SOC after completion of the charge or discharge of the battery.

8. The method of claim 1, wherein the inflow power or the outflow power of the battery is calculated based on power loss caused by internal resistance of the battery.

9. The method of claim 1, further comprising estimating the SOC value of the battery in a (k+1)^{th} cycle based on the updated state information.

10. A computer-readable recording medium having recorded thereon a program for causing a computer to execute the method of claim 1.

11. An apparatus for estimating a state of a battery, the apparatus comprising:
a memory in which at least one program is stored; and
a processor configured to perform an operation by executing the at least one program,
wherein the processor is further configured to:
obtain state information of the battery in a (k−1)^{th} cycle;
estimate a state of charge (SOC) value of the battery in a k^{th} cycle based on the obtained state information of the battery;
calculate an internal resistance value of the battery in the k^{th} cycle based on inflow power or outflow power of the battery in case that charge or discharge of the battery in the k^{th} cycle is terminated; and
update the state information of the battery in the k^{th} cycle using the calculated internal resistance value,
wherein k comprises a natural number of at least 2.

12. The apparatus of claim 11, wherein the processor is further configured to obtain the state information comprising at least one of the internal resistance value, charge/discharge current, and open circuit voltage of the battery.

13. The apparatus of claim 11, wherein the cycle comprises at least one of a process of the battery reaching a fully discharged state from a fully charged state and a process of the battery reaching the fully charged state from the fully discharged state.

14. The apparatus of claim 11, wherein the processor is further configured to obtain the state information of the battery in the (k−1)^{th} cycle corresponding to an internal resistance value included in a data sheet of the battery in case that k is 2.

15. The apparatus of claim 11, wherein the processor is further configured to estimate the SOC value of the battery based on the charge/discharge state of the battery.

16. The apparatus of claim 15, wherein the processor is further configured to:
calculate an initial value of the SOC using the open circuit voltage of the battery and the internal resistance value of the battery; and
estimate the SOC value based on the initial value of the SOC after completion of charge or discharge of the battery.

17. The apparatus of claim 16, wherein the processor is further configured to estimate the SOC value by combining an accumulated value of current flowing in according to the charge with the initial value of the SOC after completion of the charge or discharge of the battery.

18. The apparatus of claim 11, wherein the processor is further configured to calculate the inflow power or the outflow power of the battery based on power loss caused by internal resistance of the battery.

19. The apparatus of claim 11, wherein the processor is further configured to estimate the SOC value of the battery in a (k+1)^{th} cycle based on the updated state information.
